(19) United States
(12) Patent Application Publication
(10) Pub. No.: US 2023/0371172 A1
(43) Pub. Date: Nov. 16, 2023

(54) MICROSTRIP ROUTING CIRCUITS WITH DIELECTRIC FILMS

(71) Applicant: Intel Corporation, Santa Clara, CA (US)

(72) Inventors: Alberto Carrillo Vazquez, Zapopan (MX); Diego Mauricio Cortes Hernandez, Zapopan (MX); Miguel Angel Tlaxcalteco Matus, Tlaquepaque (MX); Raul Enriquez Shibayama, Zapopan (MX); Mario Alberto Velasco Gonzalez, Tlajomulco de Zúñiga (MX)

(21) Appl. No.: 17/744,359

(22) Filed: May 13, 2022

(51) Int. Cl. H05K 1/02; H01P 3/08; H01P 11/00; H05K 1/03; H05K 3/28

(52) U.S. Cl. CPC H05K 1/0231; H01P 3/081; H01P 11/003; H05K 1/0346; H05K 3/28

(57) ABSTRACT

Microstrip routing circuits with dielectric films are disclosed. A disclosed example apparatus includes a substrate, the substrate having a first side and a second side opposite the first side, the first side and the second side defining a height of the substrate, traces on the first side of the substrate, and a dielectric film positioned on the first side to cover at least a portion of the traces.

### FIELD OF THE DISCLOSURE

This disclosure relates generally to and, more particularly, to microstrip routing circuits with dielectric films.

### BACKGROUND

In recent years, high performance interface architectures, such as fifth generation Double Data Rate (DDR5), fifth generation Peripheral Component Interconnect Express (PCIE Gen5), Ethernet, etc., have increased data rates. However, these increased data rates have affected routing capabilities on printed circuit boards (PCBs) by preventing implementation of microstrip routing onto outer layers. In particular, signals propagating through the microstrip routing can be adversely affected by signal loss and crosstalk.

### BRIEF DESCRIPTION OF THE DRAWINGS

FIGS. 1A-1C depict known example microstrip routing structures in which examples disclosed herein can be implemented.

FIGS. 2A and 2B are cross-sectional views of example microstrip routing structures in accordance with teachings of this disclosure.

FIGS. 3A and 3B are cross-sectional views of alternative example microstrip routing structures in accordance with teachings of this disclosure.

FIG. 4 is a flowchart representative of an example method to produce examples disclosed herein.

FIG. 5 is an example graph representing crosstalk reduction of examples disclosed herein.

FIGS. 6A-6C are example graphs representing aspects of differential trace implementations of examples disclosed herein.

FIG. 7 is an example graph that represents crosstalk reduction corresponding to single-ended trace implementations of examples disclosed herein.

FIG. 8 depicts example results of experimental validation corresponding to examples disclosed herein.

FIG. 9 is a top view of a wafer and dies that may be included in an IC package constructed in accordance with teachings disclosed herein.

FIG. 10 is a cross-sectional side view of an IC device that may be included in an IC package constructed in accordance with teachings disclosed herein.

FIG. 11 is a cross-sectional side view of an IC package that may include and/or be applied with a dielectric film, in accordance with various examples.

FIG. 12 is a cross-sectional side view of an IC device assembly that may include an IC package constructed in accordance with teachings disclosed herein.

FIG. 13 is a block diagram of an example electrical device that may include an IC package constructed in accordance with teachings disclosed herein.

In general, the same reference numbers will be used throughout the drawing(s) and accompanying written description to refer to the same or like parts. The figures are not to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of a semiconductor device, “above” is not with reference to Earth, but instead is with reference to a bulk region of a base semiconductor substrate (e.g., a semiconductor wafer) on which components of an integrated circuit are formed. Specifically, as used herein, a first component of an integrated circuit is “above” a second component when the first component is farther away from the bulk region of the semiconductor substrate than the second component.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly that might, for example, otherwise share a same name.

As used herein, “approximately” and “about” refer to dimensions that may not be exact due to manufacturing tolerances and/or other real world imperfections. As used herein “substantially real time” refers to occurrence in a near instantaneous manner recognizing there may be real world delays for computing time, transmission, etc. Thus, unless otherwise specified, “substantially real time” refers to real time +/−1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

### DETAILED DESCRIPTION

Microstrip routing circuits with dielectric films are disclosed. In recent years, an increased speed of high performance interface architectures has negatively affected routing capabilities on printed circuit boards (PCBs). In particular, placement of microstrip routing on an outer layer of a PCB can be particularly challenging due to signal loss and crosstalk, both of which can adversely affect overall signal performance.

To address these signal issues, some known implementations utilize additional routing layers in a PCB stack-up, which can increase an overall thickness of the PCB stack-up by 20%. Further, necessitated vertical interconnection access (vias) arising from the increase in overall thickness can introduce further signal degradation. Some known implementations utilize a cable assembly. However, utilizing the cable assembly can significantly increase costs and analyzing signal characteristics of cable interconnects can take a significant amount of time. Further, it may not be possible to route all interconnects with a single cable, thereby limiting a practicality of such a solution. Some known implementations utilize an increased spacing within inner layers of a dielectric substrate, thereby reducing a routing density and a future capability to place and/or route additional devices. Additionally, in some implementations, it is not possible to increase such spacing based on size, area and/or volume limitations.

Examples disclosed herein enable effective reduction of cross-talk and signal loss for microstrip routing implementations. According to examples disclosed herein, a speed of propagation of signals in microstrip routing can be reduced, thereby reducing signal crosstalk. Further, examples disclosed herein are highly compatible with existing technologies and, in turn, can be easily added to existing implementations. Examples disclosed herein also utilize cost-effective components and/or devices, and can be manufactured in a relatively quick manner, thereby enabling relatively short production lead-times.

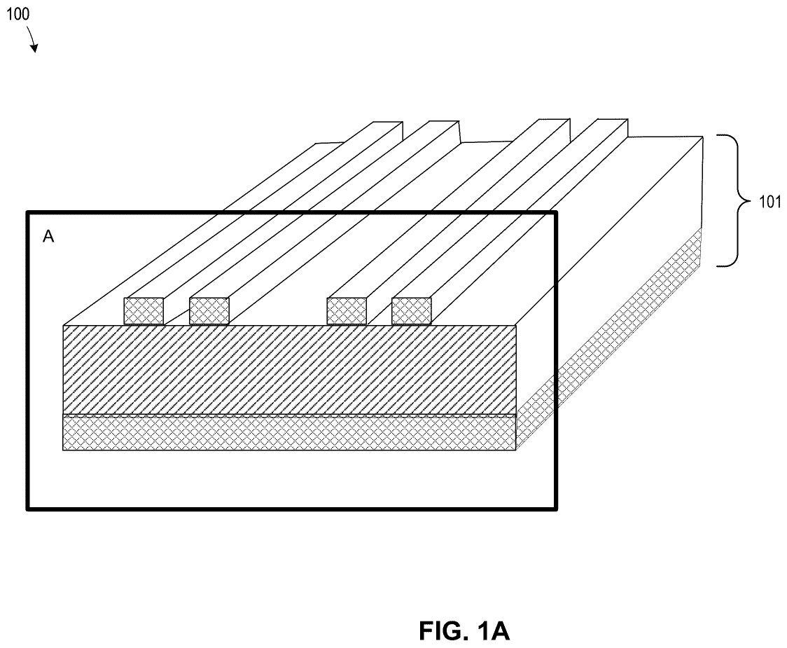

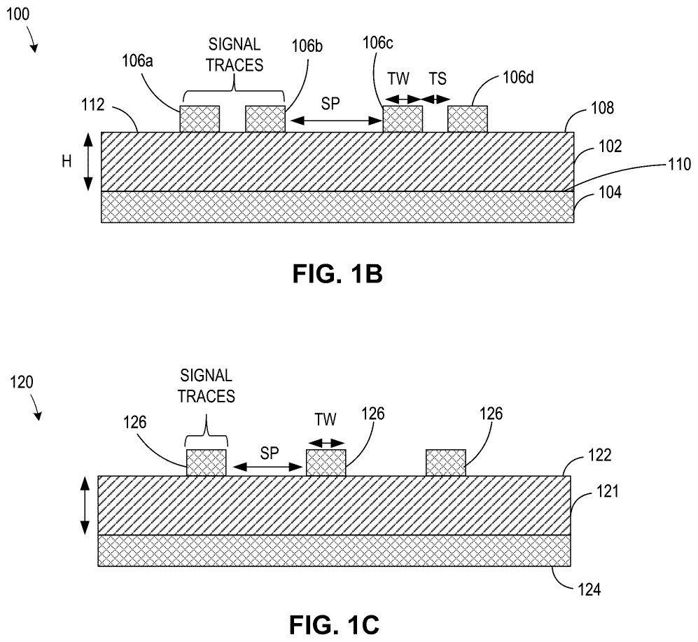

FIGS. 1A-1C depict known example microstrip routing structures in which examples disclosed herein can be implemented. FIG. 1A depicts an example circuit board (e.g., a circuit board structure, a circuit board assembly, etc.) 100. In the illustrated example, the circuit board 100 corresponds to an example differential trace implementation with a microstrip routing structure having interconnects and/or traces at exterior/outer surfaces thereof. Further, the circuit board 100 of the illustrated example includes a stacked layered structure (e.g., a multi-layered structure) 101 which, in turn, includes multiple dielectric layers (e.g., substrate layers) and ground layers with interconnects and routing extending therein.

FIGS. 1B and 1C are cross-sectional views of example microstrip routing structures in which examples disclosed herein can be implemented. FIG. 1B depicts a cross-sectional view of the aforementioned circuit board 100 along a plane A shown in FIG. 1A. The example circuit board 100 corresponds to a differential trace architecture and includes a substrate (e.g., a dielectric substrate, at least one dielectric layer) 102, which can be at least partially composed of an FR-4 material, and a ground layer (e.g., an isolating ground layer) 104. In this example, the substrate 102 supports differential traces (e.g., terminals, interconnects, etc.) 106 (hereinafter traces 106a, 106b, 106c, 106d) on a first side 108 of the substrate 102, and a ground layer (e.g., a ground plane, an isolating ground layer) 104 on a second side 110 of the substrate 102 that is opposite to the first side 108. Further, the aforementioned traces 106 are positioned on an outer surface (e.g., an exposed outer surface, an etched outer surface, a cut/routed outer surface) 112 on the first side 108 of the substrate 102. In this example, the traces 106a, 106b correspond to a first differential pair while the traces 106c, 106d correspond to a second differential pair that is spatially offset from the first differential pair.

According to examples disclosed herein, “SP” denotes a pitch distance, “TW” denotes a trace width, and “TS” denotes trace spacing. Further, “H” denotes a thickness of the aforementioned substrate 102 defined by the first side 108 and the second side 110. These parameters shown in FIG. 1B can be related to and/or affect an impedance of the circuit board 100, for example.

FIG. 1C depicts an example implementation of a microstrip routing implementation corresponding to a single-ended trace architecture. In the illustrated example of FIG. 1C, an example circuit board 120 includes a substrate 121 with a respective outer surface 122. Further, in this example, the substrate 121 is adjacent and/or coupled to a ground layer 124, and supports signal traces 126, which are single-ended traces, for example. The example signal traces 126 are positioned on and supported by the outer surface 122, which corresponds to an etched region and/or area of the substrate 121.

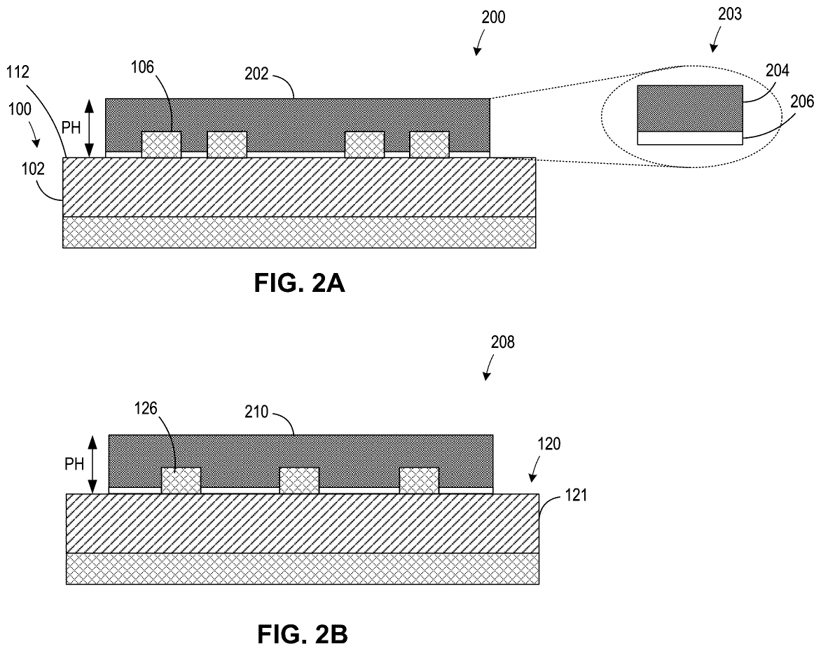

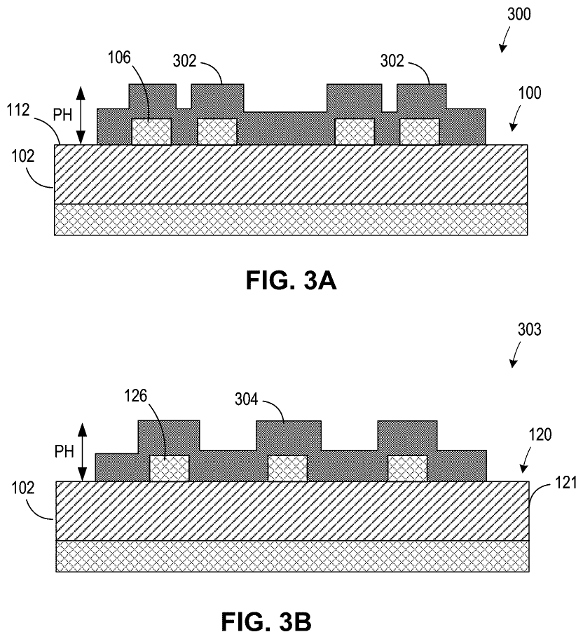

FIGS. 2A and 2B are cross-sectional views of example microstrip routing structures in accordance with teachings of this disclosure. Turning to FIG. 2A, an example PCB assembly 200 is shown with the circuit board 100 and an example dielectric film (e.g., a dielectric thin film, a dielectric layer, etc.) 202 positioned thereon. In this example, the dielectric film 202 is applied to the circuit board 100 as an adhesive tape (e.g., a die-cut adhesive tape). In the illustrated example of FIG. 2A, a detail 203 depicts the dielectric film 202 having a dielectric layer (e.g., a dielectric thin film layer) 204 and an adhesive layer 206. Alternatively, in some other examples, a dielectric film is applied as a coating (e.g., a conformal coating, a liquid coating, etc.), as described below in connection with FIGS. 3A and 3B.

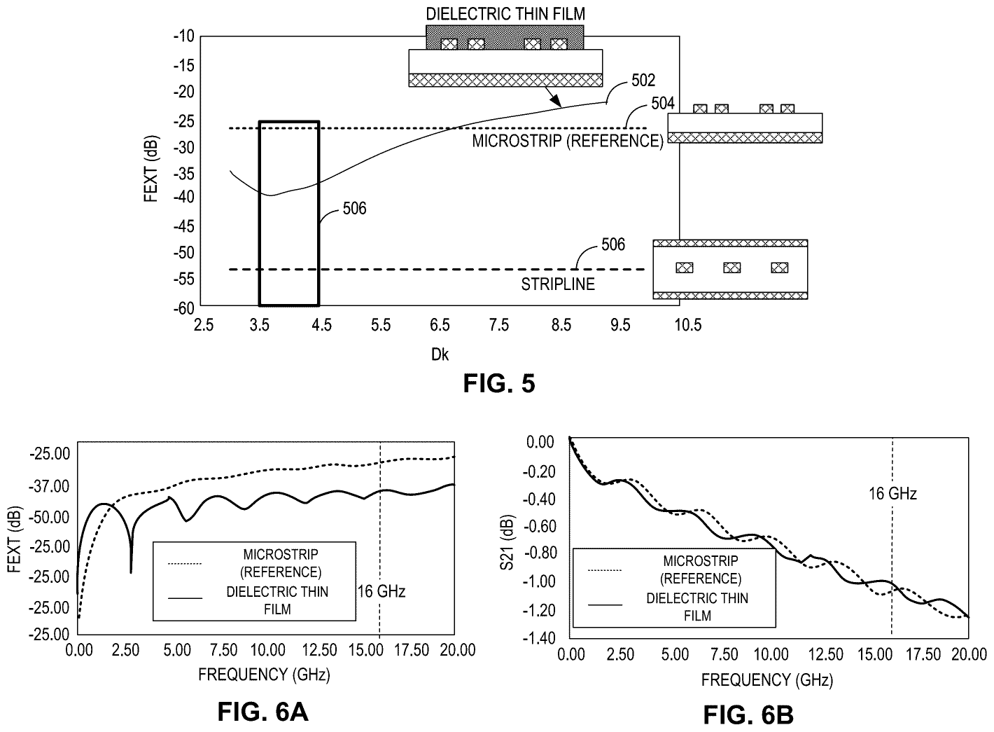

To vary and/or control at least one electrical and/or signal quality characteristic of the example circuit board 100, the dielectric film 202 covers and/or envelops the traces 106 on the outer surface 112. In particular, covering the traces 106 reduces cross-talk therebetween, as will be described in greater detail below in connection with FIGS. 5-8. Further, examples disclosed herein can greatly reduce signal degradation. Particularly, the dielectric film 202 of the illustrated example can maintain an impedance at a relatively stable and/or constant level. According to some examples, parameters of the dielectric film 202 are selected so that the example microstrip routing circuit 200 has an associated impedance of approximately 80-90Ω (e.g., 85Ω). Additionally or alternatively, properties of the dielectric film 202 (e.g., a thickness of the dielectric film 202, a material of the dielectric film 202, etc.) in conjunction with a width and a spacing (e.g., a pitch) of the traces 106 are simulated so that the associated impedance is approximately 85Ω. However, any other appropriate impedance values and/or ranges can be implemented instead. In some examples, the traces 106 are positioned at a recess of the substrate 102 and/or a recess defined by the outer surface 112.

According to some examples disclosed herein, the substrate 102 can have a same or similar thickness/height to a thickness/height of the dielectric film 202, which is denoted by “PH” in FIG. 2A. For example, a ratio between the thickness/height of the substrate 102 and the thickness/height of the dielectric film 202 is in a range from approximately 0.90 to 1.10.

Some examples implement polyester films in the dielectric film 202. For example, the polyester films that can be implemented in examples disclosed herein include, but are not limited to, polyethylene terephthalate (PET), polyethylene naphthalate (PEN), PET films such as Mylar® or Melinex® having a dielectric constant (Dk) of approximately 3.0, a PEN material, such as Teonex with a Dk value of approximately 2.95, etc. In some examples, polyether films, such as Ultem 1000® with a Dk value of approximately 3.15 are implemented in the dielectric film 202. Additionally or alternatively, polyamide materials, such as polyimide films including Kapton®, Vespel®, and Cirlex® with a Dk value in a range from approximately 3.4 to 3.7, for example, are implemented in examples disclosed herein. In some examples, to reduce cross talk between the traces 106, the dielectric film 202 has a Dk value in a range from approximately 3.0 to 4.5. Additionally or alternatively, an additional grounding layer is placed at or proximate the outer surface 112.

FIG. 2B depicts an example PCB assembly 208 having the example circuit board 120 with a dielectric film 210 applied thereto to cover (e.g., fully cover and encapsulate) the aforementioned single-ended traces 126. In particular, the example of FIG. 2B is similar to that of FIG. 2A, but utilizes the single-ended traces 126 instead of the differential traces 106. Similar to the example FIG. 2A, the dielectric film 210 is applied to the substrate 121 as an adhesive and/or tape. As a result, at least one electrical and/or signal characteristic of the aforementioned circuit board 120 is varied, altered and/or controlled.

FIGS. 3A and 3B are cross-sectional views of alternative example microstrip routing structures in accordance with teachings of this disclosure. Turning to FIG. 3A, in the illustrated example, a circuit board 300 includes the circuit board 100 and a dielectric film 302 applied over the surface 112 of the substrate 102 as a conformal coating to cover, envelop and/or surround the traces 106. In this example, the surface 112 is at least partially defined based on an etching process performed on and/or adjacent a side (e.g., a top side, a bottom side, etc.) of a metal layer associated with the substrate 102 to expose the traces 106. Similar to other examples disclosed herein, the dielectric film 302 can reduce cross-talk associated with the terminals 106, amongst other advantages.

In some examples, the dielectric film 302 is applied as a conformal coating with a relatively constant thickness (e.g., a relatively uniform thickness) across a span (e.g., an entirety of an area) of the outer surface 112 (e.g., the thickness varies less than 10% across a span and/or area of the outer surface 112). In particular examples, the thickness of the dielectric film can be generally uniform such that the thickness varies by less than 5% across a span thereof. In some other examples, a height of the conformal coating contacting the traces 106 is thinner in some regions than one or more heights of other regions of the conformal coating contacting the surface 112. Additionally or alternatively, a thickness of the dielectric film 302 varies across a span (e.g., a lateral width) of the outer surface 112 (e.g., the thickness of the dielectric film 302 linearly varies across a side and/or a lateral direction of the substrate 102). In some such examples, the varying thickness can be utilized to tune and/or customize at least one electrical or signal property of the circuit board 100 and/or the traces 106. In some particular examples, the outer surface 112 is angled, locally cut and/or uneven to enable a varying thickness of the dielectric film 302. In some examples, the dielectric film 302 does not cover at least a portion of the outer surface 112 (e.g., a portion of the outer surface 112 positioned at requisite distance away from the traces 106).

FIG. 3B depicts a PCB assembly 303, which includes the example circuit board 120 and a dielectric film 304 applied to the circuit board 120 to cover the single-ended traces 126. Similar to the example of FIG. 3A, the dielectric film 304 is applied to the substrate 121 as a conformal coating to cover, enclose and/or surround the traces 126. As a result, at least one electrical characteristic of the aforementioned circuit board 120 is varied, altered and/or controlled. In some examples, the dielectric film 304 is applied to a recess and/or depth of the substrate 121.

Any of the features and/or aspects described above in connection with FIGS. 1A-3B can be implemented with and/or in combination with any other example implementation described herein. In other words, any aspects and/or features described in conjunction with an example can be applied to any other example(s) disclosed herein.

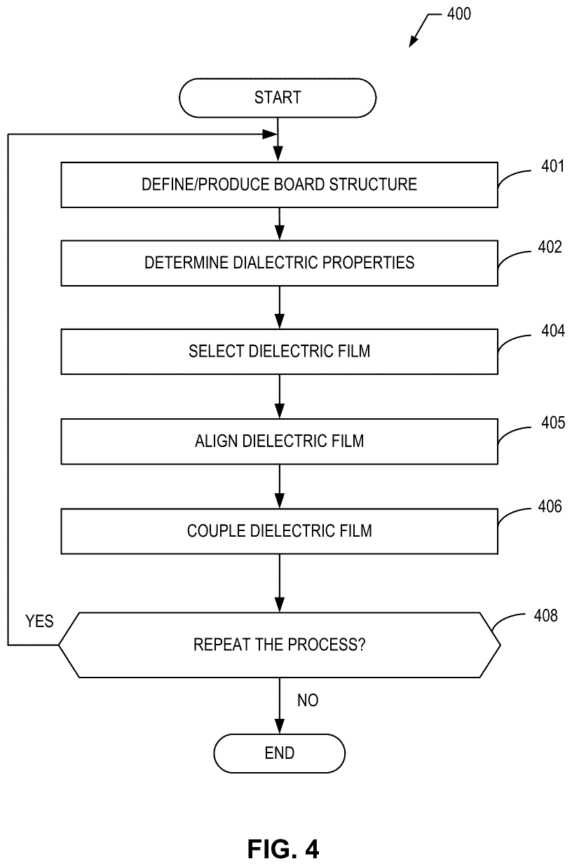

FIG. 4 is a flowchart representative of an example method 400 to produce examples disclosed herein. In this example, a circuit board (e.g., the circuit board 100, the circuit board 120) is to be integrated with and/or applied with a dielectric film (e.g., the dielectric film 202, the dielectric film 210, the dielectric film 302, the dielectric film 304), thereby varying and/or adjusting at least one electrical characteristic associated with component(s) of the circuit board and/or their operation.

At block 401, the circuit board is defined/produced. In this example, the circuit board is defined, produced and/or fabricated such that traces (e.g., the traces 106, 126) are defined thereon and/or exposed on an outer surface/side of the circuit board.

At block 402, in some examples, the dielectric properties of the circuit board are determined. In some such examples, the dielectric properties are simulated (e.g., to determine a characteristic impedance associated with the circuit board). Additionally or alternatively, parameters and/or characteristics of the dielectric layer are determined (e.g., optimized) so that the circuit board and the dielectric film have an impedance value that is relatively constant at a defined value and/or range (e.g., 85Ω). In some examples, trace width and/or spacing of the traces on the circuit board is varied so that the impedance value remains relatively constant at the defined value and/or range.

At block 404, in some examples, a dielectric film is selected based on the determined dielectric properties of the circuit board and/or an overall dielectric constant of the circuit board and the dielectric film. In some examples, the dielectric film is selected based on a desired impedance value.

At block 405, in some examples, the dielectric film is aligned to the circuit board. In some such examples, the dielectric film is aligned to an etched region of the circuit board. Additionally or alternatively, the dielectric film is aligned to a reference feature and/or geometry associated with the circuit board.

At block 406, the dielectric film is coupled to an outer side of the circuit board. As a result, traces of the outer surface are covered by the dielectric film. In some examples, the dielectric film is applied as an adhesive. In other examples, the dielectric film is applied as a conformal coating (e.g., a liquid conformal coating, a spray conformal coating, etc.).

FIG. 5 is an example graph representing crosstalk reduction of examples disclosed herein. In the illustrated example of FIG. 5, a far end cross talk (FEXT) reduction of examples disclosed herein is represented with respect to dielectric constant values. In this example, a line 502 depicts a microstrip routing circuit board implementation with a dielectric film in accordance with teachings of this disclosure while a line 504 depicts a known (e.g., reference) microstrip routing circuit implementation without a dielectric film, and a line 506 depicts a known stripline implementation, which can involve significant cost, complexity and overall volume in contrast to examples disclosed herein. As can be seen in FIG. 5, across certain Dk value ranges (e.g., a range from 3.5 to 4.5 demarcated by a box 508), FEXT can be significantly reduced (e.g., by approximately 50%) relative to the reference microstrip routing circuit implementation. Further, in some examples, a Dk value of approximately 3.0 can yield favorable results for some applications. According to some examples, a dielectric layer thickness of approximately 0.175 millimeters can significantly reduce FEXT (in certain applications). However, any other appropriate thickness can be implemented based on application requirements and/or impedance-related parameters.

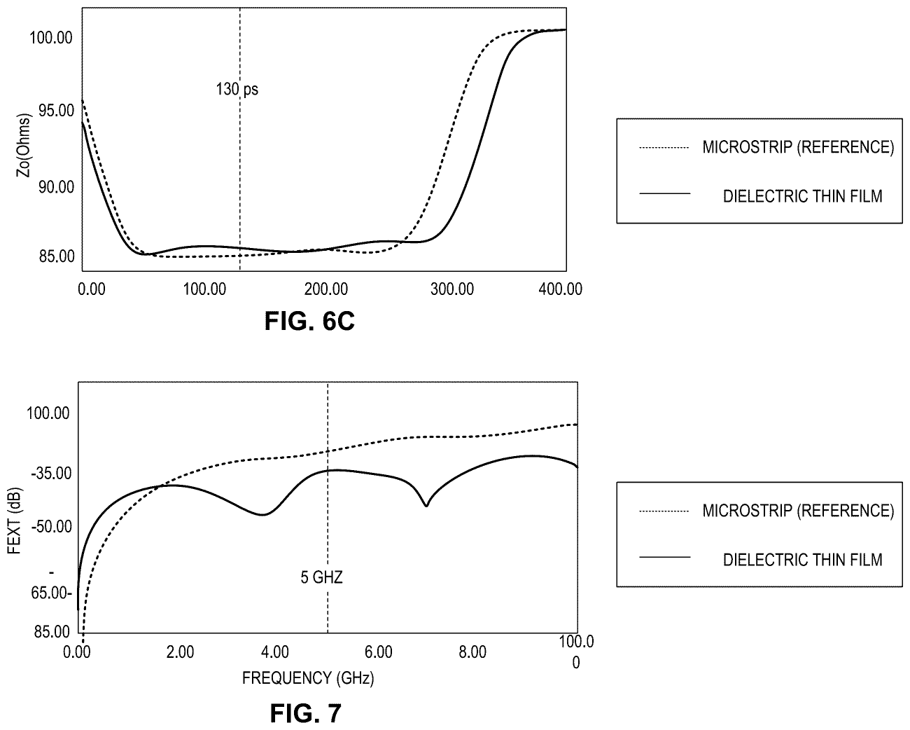

FIGS. 6A-6C are example graphs representing aspects of differential trace implementations of examples disclosed herein. Turning to FIG. 6A, an example graph depicts crosstalk shown in relation to frequency. In the example of FIG. 6A, a comparison of the FEXT versus the frequency with and without the dielectric film (e.g., after optimization of both aforementioned scenarios) is shown. Based on the graph of FIG. 6A, if the dielectric layer is placed onto the microstrip routing circuit/interconnect, the FEXT is significantly reduced in comparison to the reference baseline, which is not utilizing a dielectric film (denoted by a dotted line). In this particular example, at a frequency value of approximately 16 gigahertz (GHz), FEXT is reduced from approximately −26.60 decibels (dB) to −40.13 dB.

Turning to FIG. 6B, an example graph is shown representing insertion loss (S21) between an example configuration utilizing a dielectric film and a baseline reference (dotted line) that does not implement the dielectric film. Accordingly, a difference in insertion loss is not significant between both of the shown scenarios.

FIG. 6C is an example graph depicting impedance (Zo) with respect to time. In the illustrated example of FIG. 6C, the impedance remains relatively constant at approximately 85 n.

In regard to differential traces as shown in FIGS. 6A-6C, examples disclosed herein have been verified by simulation and experimentation. In some examples, differential traces have a length of approximately 1000 mil and a spacing between differential pairs (SP) of approximately 10 mil with an isolation cover having a thickness (PH) of approximately 10 mil, such that geometry of interconnects before providing the dielectric film includes a trace width (TW) of approximately 4.8 mil, trace spacing (TS) of approximately 6.4 mil, and a dielectric height (H) of approximately 2.7 mil routed with an Ultra-Low Loss category 1 material. According to examples disclosed herein, once the dielectric film covers microstrip traces, an optimization of a geometry of a corresponding transmission line enables calculation of updated TW and TS values:TW=4.2 mil and TS=7.6 mil, thereby enabling an approximate impedance of 85Ω. In some examples, there can be a difference of less than 20% in geometry and/or dimensions subsequent to providing the dielectric film to cover the interconnects.

FIG. 7 is an example graph that represents crosstalk reduction corresponding to single-ended trace implementations of examples disclosed herein. As can be seen in FIG. 7, benefits for single-ended interconnects are similar to that of differential traces. The geometry before the dielectric film is optimized is a TW of 6.9 mil, and after optimization the TW is equal to approximately 6.2 mil. In other words, a thickness of a dielectric film can be adjusted to improve electrical and/or signal performance of examples disclosed herein. In this example, trace to trace spacing is approximately 17 mil. In the example of FIG. 7, a reduction of the FEXT at 5 GHz with a dielectric thin film is shown.

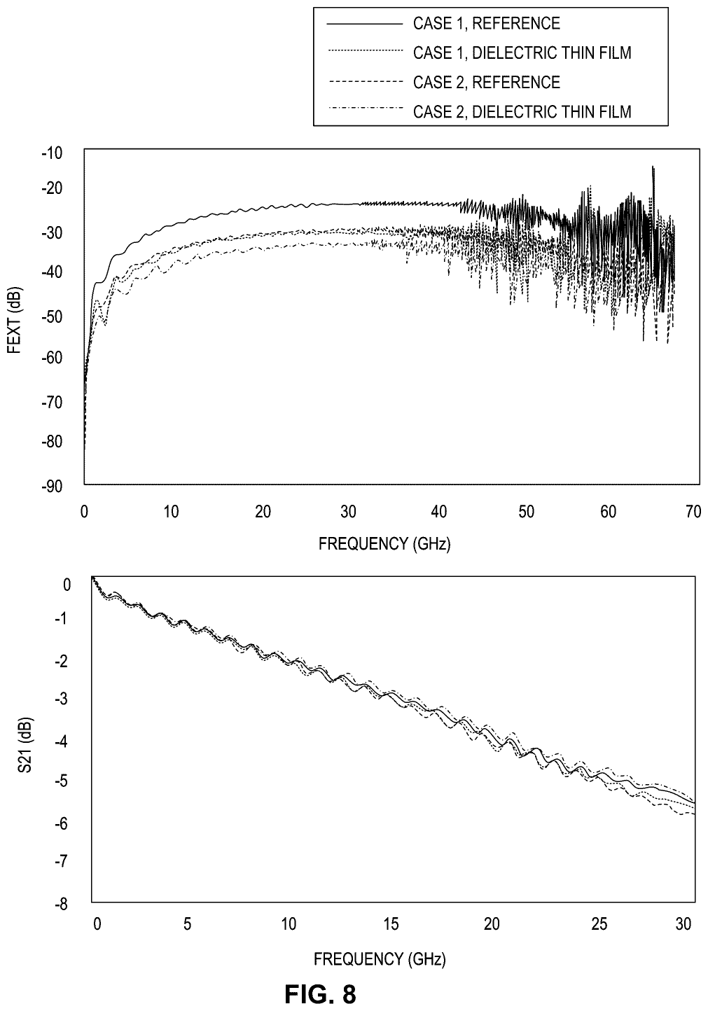

FIG. 8 depicts example results of experimental validation. A prototype utilized for the graphs of FIG. 8 included a polyamide tape covering differential trace pairs. In particular, case 1 pertains to a first differential trace pair and case 2 pertains to a second differential trace pair having a larger degree of spacing (TS) therebetween. In the illustrated example of FIG. 8, results pertaining to FEXT of scenarios with and without the polyamide tape are shown. As can be seen in the example graphs of FIG. 8, there is a significant reduction of the FEXT for both cases when the polyamide tape covers the differential traces. Further, the insertion loss (S21) presented in FIG. 8 indicates that there is not a significant change thereof for insertion loss. The example results of FIG. 8 align closely with the trends shown in FIGS. 6A-6C.

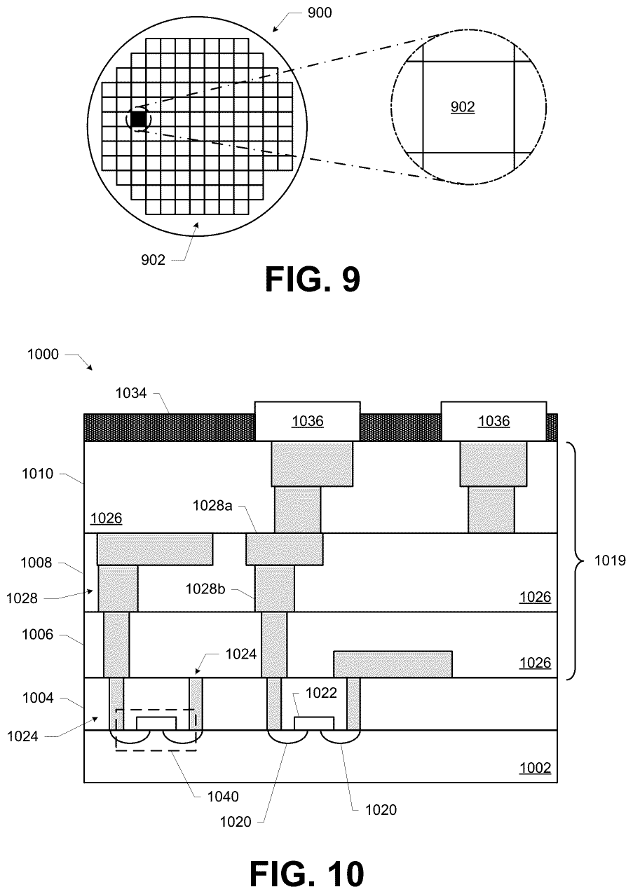

The example dielectric films disclosed herein may be included in any suitable electronic component. FIGS. 9-13 illustrate various examples of apparatus that may include or be included in the dielectric films disclosed herein.

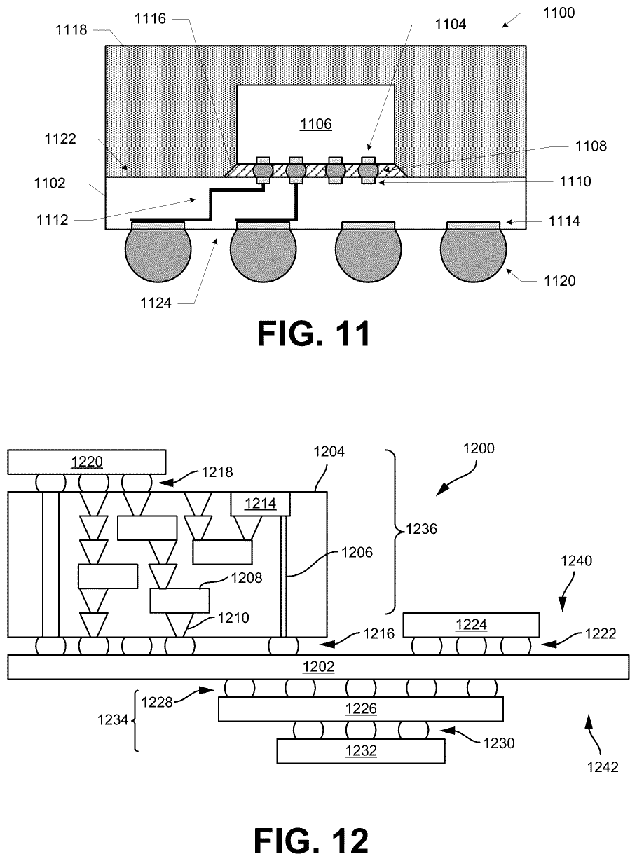

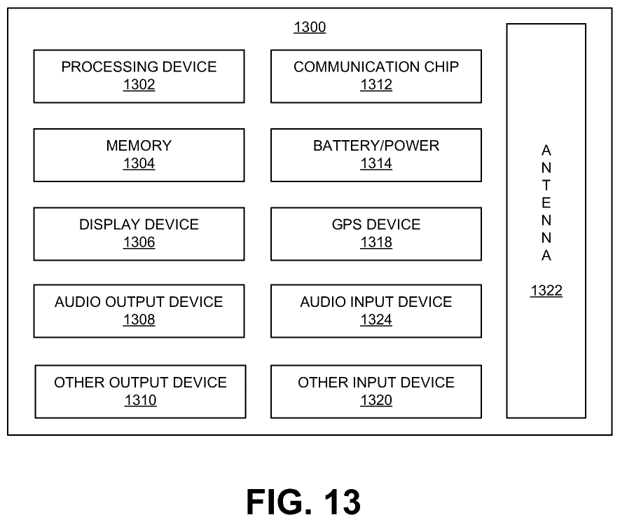

FIG. 9 is a top view of a wafer 900 and dies 902 that may be included in an IC package whose substrate includes and/or is applied with one or more dielectric films (e.g., as discussed below with reference to FIG. 11) in accordance with any of the examples disclosed herein. The wafer 900 may be composed of semiconductor material and may include one or more dies 902 having IC structures formed on a surface of the wafer 900. Each of the dies 902 may be a repeating unit of a semiconductor product that includes any suitable IC. After the fabrication of the semiconductor product is complete, the wafer 900 may undergo a singulation process in which the dies 902 are separated from one another to provide discrete “chips” of the semiconductor product. The die 902 may include one or more transistors (e.g., some of the transistors 1040 of FIG. 10, discussed below), supporting circuitry to route electrical signals to the transistors, passive components (e.g., signal traces, resistors, capacitors, or inductors), and/or any other IC components. In some examples, the wafer 900 or the die 902 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 902. For example, a memory array formed by multiple memory devices may be formed on a same die 1902 as a processing device (e.g., the processing device 1302 of FIG. 13) or other logic that is configured to store information in the memory devices or execute instructions stored in the memory array. Examples disclosed herein may be manufactured using a die-to-wafer assembly technique in which some dies are attached to a wafer 1900 that include others of the dies, and the wafer 1900 is subsequently singulated.

FIG. 10 is a cross-sectional side view of an IC device 1000 that may be included in an IC package whose substrate includes and/or is applied with one or more dielectric films (e.g., as discussed below with reference to FIG. 11), in accordance with any of the examples disclosed herein. One or more of the IC devices 1000 may be included in one or more dies 902 (FIG. 9). The IC device 1000 may be formed on a die substrate 1002 (e.g., the wafer 900 of FIG. 9) and may be included in a die (e.g., the die 902 of FIG. 9). The die substrate 2002 may be a semiconductor substrate composed of semiconductor material systems including, for example, n-type or p-type materials systems (or a combination of both). The die substrate 1002 may include, for example, a crystalline substrate formed using a bulk silicon or a silicon-on-insulator (SOI) substructure. In some examples, the die substrate 1002 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the die substrate 1002. Although a few examples of materials from which the die substrate 1002 may be formed are described here, any material that may serve as a foundation for an IC device 1000 may be used. The die substrate 1002 may be part of a singulated die (e.g., the dies 902 of FIG. 9) or a wafer (e.g., the wafer 900 of FIG. 9).

The IC device 1000 may include one or more device layers 2004 disposed on the die substrate 1002. The device layer 1004 may include features of one or more transistors 1040 (e.g., metal oxide semiconductor field-effect transistors (MOSFETs)) formed on the die substrate 1002. The device layer 2004 may include, for example, one or more source and/or drain (S/D) regions 2020, a gate 2022 to control current flow in the transistors 1040 between the S/D regions 1020, and one or more S/D contacts 1024 to route electrical signals to/from the S/D regions 1020. The transistors 1040 may include additional features not depicted for the sake of clarity, such as device isolation regions, gate contacts, and the like. The transistors 1040 are not limited to the type and configuration depicted in FIG. 10 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1040 may include a gate 1022 formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some examples, an annealing process may be carried out on the gate dielectric to improve its quality when a high-k material is used.

The gate electrode may be formed on the gate dielectric and may include at least one p-type work function metal or n-type work function metal, depending on whether the transistor 1040 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer. For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some examples, when viewed as a cross-section of the transistor 1040 along the source-channel-drain direction, the gate electrode may consist of a U-shaped structure that includes a bottom portion substantially parallel to the surface of the die substrate 1002 and two sidewall portions that are substantially perpendicular to the top surface of the die substrate 1002. In other examples, at least one of the metal layers that form the gate electrode may simply be a planar layer that is substantially parallel to the top surface of the die substrate 1002 and does not include sidewall portions substantially perpendicular to the top surface of the die substrate 1002. In other examples, the gate electrode may consist of a combination of U-shaped structures and planar, non-U-shaped structures. For example, the gate electrode may consist of one or more U-shaped metal layers formed atop one or more planar, non-U-shaped layers.

In some examples, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some examples, a plurality of spacer pairs may be used; for instance, two pairs, three pairs, or four pairs of sidewall spacers may be formed on opposing sides of the gate stack.

The S/D regions 1020 may be formed within the die substrate 1002 adjacent to the gate 1022 of each transistor 1040. The S/D regions 1020 may be formed using an implantation/diffusion process or an etching/deposition process, for example. In the former process, dopants such as boron, aluminum, antimony, phosphorous, or arsenic may be ion-implanted into the die substrate 1002 to form the S/D regions 1020. An annealing process that activates the dopants and causes them to diffuse farther into the die substrate 1002 may follow the ion-implantation process. In the latter process, the die substrate 1002 may first be etched to form recesses at the locations of the S/D regions 1020. An epitaxial deposition process may then be carried out to fill the recesses with material that is used to fabricate the S/D regions 1020. In some implementations, the S/D regions 1020 may be fabricated using a silicon alloy such as silicon germanium or silicon carbide. In some examples, the epitaxially deposited silicon alloy may be doped in situ with dopants such as boron, arsenic, or phosphorous. In some examples, the S/D regions 1020 may be formed using one or more alternate semiconductor materials such as germanium or a group III-V material or alloy. In further examples, one or more layers of metal and/or metal alloys may be used to form the S/D regions 1020.

Electrical signals, such as power and/or input/output (I/O) signals, may be routed to and/or from the devices (e.g., transistors 1040) of the device layer 1004 through one or more interconnect layers disposed on the device layer 1004 (illustrated in FIG. 10 as interconnect layers 1006-1010). For example, electrically conductive features of the device layer 1004 (e.g., the gate 1022 and the S/D contacts 1024) may be electrically coupled with the interconnect structures 1028 of the interconnect layers 1006-1010. The one or more interconnect layers 1006-1010 may form a metallization stack (also referred to as an “ILD stack”) 1019 of the IC device 1000.

The interconnect structures 1028 may be arranged within the interconnect layers 1006-1010 to route electrical signals according to a wide variety of designs (in particular, the arrangement is not limited to the particular configuration of interconnect structures 1028 depicted in FIG. 10). Although a particular number of interconnect layers 1006-1010 is depicted in FIG. 10, examples of the present disclosure include IC devices having more or fewer interconnect layers than depicted.

In some examples, the interconnect structures 1028 may include lines 1028a and/or vias 1028b filled with an electrically conductive material such as a metal. The lines 1028a may be arranged to route electrical signals in a direction of a plane that is substantially parallel with a surface of the die substrate 1002 upon which the device layer 1004 is formed. For example, the lines 1028a may route electrical signals in a direction in and out of the page from the perspective of FIG. 10. The vias 1028b may be arranged to route electrical signals in a direction of a plane that is substantially perpendicular to the surface of the die substrate 1002 upon which the device layer 1004 is formed. In some examples, the vias 1028b may electrically couple lines 1028a of different interconnect layers 1006-1010 together.

The interconnect layers 1006-1010 may include a dielectric material 1026 disposed between the interconnect structures 1028, as shown in FIG. 10. In some examples, the dielectric material 1026 disposed between the interconnect structures 1028 in different ones of the interconnect layers 1006-1010 may have different compositions; in other examples, the composition of the dielectric material 1026 between different interconnect layers 1006-1010 may be the same.

A first interconnect layer 106 (referred to as Metal 1 or “M1”) may be formed directly on the device layer 1004. In some examples, the first interconnect layer 1006 may include lines 1028a and/or vias 1028b, as shown. The lines 1028a of the first interconnect layer 1006 may be coupled with contacts (e.g., the S/D contacts 1024) of the device layer 1004.

A second interconnect layer 1008 (referred to as Metal 2 or “M2”) may be formed directly on the first interconnect layer 1006. In some examples, the second interconnect layer 1008 may include vias 1028b to couple the lines 1028a of the second interconnect layer 1008 with the lines 1028a of the first interconnect layer 1006. Although the lines 1028a and the vias 1028b are structurally delineated with a line within each interconnect layer (e.g., within the second interconnect layer 1008) for the sake of clarity, the lines 1028a and the vias 1028b may be structurally and/or materially contiguous (e.g., simultaneously filled during a dual-damascene process) in some examples.

A third interconnect layer 1010 (referred to as Metal 3 or “M3”) (and additional interconnect layers, as desired) may be formed in succession on the second interconnect layer 1008 according to similar techniques and configurations described in connection with the second interconnect layer 1008 or the first interconnect layer 1006. In some examples, the interconnect layers that are “higher up” in the metallization stack 1019 in the IC device 1000 (i.e., further away from the device layer 1004) may be thicker.

The IC device 1000 may include a solder resist material 1034 (e.g., polyimide or similar material) and one or more conductive contacts 1036 formed on the interconnect layers 1006-1010. In FIG. 10, the conductive contacts 2036 are illustrated as taking the form of bond pads. The conductive contacts 2036 may be electrically coupled with the interconnect structures 2028 and configured to route the electrical signals of the transistor(s) 1040 to other external devices. For example, solder bonds may be formed on the one or more conductive contacts 1036 to mechanically and/or electrically couple a chip including the IC device 1000 with another component (e.g., a circuit board). The IC device 1000 may include additional or alternate structures to route the electrical signals from the interconnect layers 1006-1010; for example, the conductive contacts 1036 may include other analogous features (e.g., posts) that route the electrical signals to external components.

FIG. 11 is a cross-sectional view of an example IC package 1100 that may include and be applied with one or more dielectric films. The package substrate 1102 may be formed of a dielectric material, and may have conductive pathways extending through the dielectric material between upper and lower faces 1122, 1124, or between different locations on the upper face 1122, and/or between different locations on the lower face 1124. These conductive pathways may take the form of any of the interconnects 1028 discussed above with reference to FIG. 10. In some examples, any number of dielectric films (with any suitable structure) may be included in and/or applied to a package substrate 1102. In some examples, no dielectric films may be included in the package substrate 1102.

The IC package 1100 may include a die 1106 coupled to the package substrate 1102 via conductive contacts 1104 of the die 1106, first-level interconnects 1108, and conductive contacts 1110 of the package substrate 1102. The conductive contacts 1110 may be coupled to conductive pathways 1112 through the package substrate 1102, allowing circuitry within the die 1106 to electrically couple to various ones of the conductive contacts 1114 (or to other devices included in the package substrate 1102, not shown). The first-level interconnects 1108 illustrated in FIG. 11 are solder bumps, but any suitable first-level interconnects 1108 may be used. As used herein, a “conductive contact” may refer to a portion of conductive material (e.g., metal) serving as an electrical interface between different components; conductive contacts may be recessed in, flush with, or extending away from a surface of a component, and may take any suitable form (e.g., a conductive pad or socket).

In some examples, an underfill material 1116 may be disposed between the die 1106 and the package substrate 1102 around the first-level interconnects 1108, and a mold compound 1118 may be disposed around the die 1106 and in contact with the package substrate 1102. In some examples, the underfill material 1116 may be the same as the mold compound 1118. Example materials that may be used for the underfill material 1116 and the mold compound 1118 are epoxy mold materials, as suitable. Second-level interconnects 1120 may be coupled to the conductive contacts 1114. The second-level interconnects 1120 illustrated in FIG. 11 are solder balls (e.g., for a ball grid array arrangement), but any suitable second-level interconnects 1120 may be used (e.g., pins in a pin grid array arrangement or lands in a land grid array arrangement). The second-level interconnects 1120 may be used to couple the IC package 1100 to another component, such as a circuit board (e.g., a motherboard), an interposer, or another IC package, as known in the art and as discussed below with reference to FIG. 12.

In FIG. 11, the IC package 1100 is a flip chip package, and includes and/or is applied with a dielectric film in the package substrate 1102. The number and location of dielectric films in the package substrate 1102 of the IC package 2100 is simply illustrative, and any number of dielectric films (with any suitable structure) may be included in and/or on a package substrate 1102. In some examples, no dielectric films may be included in the package substrate 1102. The die 1106 may take the form of any of the examples of the die 1302 discussed herein (e.g., may include any of the examples of the IC device 1000). In some examples, the die 1106 may include and/or be applied with one or more dielectric films (e.g., as discussed above with reference to FIG. 9 and FIG. 10); in other examples, the die 1106 may not include any dielectric films.

Although the IC package 1100 illustrated in FIG. 11 is a flip chip package, other package architectures may be used. For example, the IC package 1100 may be a ball grid array (BGA) package, such as an embedded wafer-level ball grid array (eWLB) package. In another example, the IC package 1100 may be a wafer-level chip scale package (WLCSP) or a panel fanout (FO) package. Although a single die 1106 is illustrated in the IC package 1100 of FIG. 11, an IC package 1100 may include multiple dies 1106 (e.g., with one or more of the multiple dies 1106 coupled to and/or applied with dielectric film(s) included in the package substrate 1102). An IC package 1100 may include additional passive components, such as surface-mount resistors, capacitors, and inductors disposed on the first face 1122 or the second face 1124 of the package substrate 1102. More generally, an IC package 1100 may include any other active or passive components known in the art.

FIG. 12 is a cross-sectional side view of an IC device assembly 1200 that may include and/or applied with the dielectric films disclosed herein. In some examples, the IC device assembly corresponds to the dielectric films. The IC device assembly 1200 includes a number of components disposed on a circuit board 1202 (which may be, for example, a motherboard). The IC device assembly 1200 includes components disposed on a first face 1240 of the circuit board 1202 and an opposing second face 1242 of the circuit board 1202; generally, components may be disposed on one or both faces 1240 and 1242.

In some examples, the circuit board 1202 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1202. In other examples, the circuit board 1202 may be a non-PCB substrate.

The IC device assembly 1200 illustrated in FIG. 12 includes a package-on-interposer structure 1236 coupled to the first face 1240 of the circuit board 1202 by coupling components 1216. The coupling components 1216 may electrically and mechanically couple the package-on-interposer structure 1236 to the circuit board 1202, and may include solder balls (as shown in FIG. 12), male and female portions of a socket, an adhesive, an underfill material, and/or any other suitable electrical and/or mechanical coupling structure.

The package-on-interposer structure 1236 may include an IC package 1220 coupled to an interposer 1204 by coupling components 1218. The coupling components 1218 may take any suitable form for the application, such as the forms discussed above with reference to the coupling components 1216. Although a single IC package 1220 is shown in FIG. 12, multiple IC packages may be coupled to the interposer 1204; indeed, additional interposers may be coupled to the interposer 1204. The interposer 1204 may provide an intervening substrate used to bridge the circuit board 1202 and the IC package 1220. The IC package 1220 may be or include, for example, a die (the die 902 of FIG. 9), an IC device (e.g., the IC device 1000 of FIG. 10), or any other suitable component. Generally, the interposer 1204 may spread a connection to a wider pitch or reroute a connection to a different connection. For example, the interposer 1204 may couple the IC package 1220 (e.g., a die) to a set of BGA conductive contacts of the coupling components 1216 for coupling to the circuit board 2202. In the example illustrated in FIG. 12, the IC package 1220 and the circuit board 1202 are attached to opposing sides of the interposer 1204; in other examples, the IC package 1220 and the circuit board 1202 may be attached to a same side of the interposer 1204. In some examples, three or more components may be interconnected by way of the interposer 1204.

In some examples, the interposer 1204 may be formed as a PCB, including multiple metal layers separated from one another by layers of dielectric material and interconnected by electrically conductive vias. In some examples, the interposer 1204 may be formed of an epoxy resin, a fiberglass-reinforced epoxy resin, an epoxy resin with inorganic fillers, a ceramic material, or a polymer material such as polyimide. In some examples, the interposer 1204 may be formed of alternate rigid or flexible materials that may include the same materials described above for use in a semiconductor substrate, such as silicon, germanium, and other group III-V and group IV materials. The interposer 2204 may include metal interconnects 1208 and vias 1210, including but not limited to through-silicon vias (TSVs) 1206. The interposer 1204 may further include embedded devices 1214, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1204. The package-on-interposer structure 1236 may take the form of any of the package-on-interposer structures known in the art.

The IC device assembly 1200 may include an IC package 1224 coupled to the first face 1240 of the circuit board 1202 by coupling components 1222. The coupling components 1222 may take the form of any of the examples discussed above with reference to the coupling components 1216, and the IC package 1224 may take the form of any of the examples discussed above with reference to the IC package 1220.

The IC device assembly 1200 illustrated in FIG. 12 includes a package-on-package structure 1234 coupled to the second face 1242 of the circuit board 1202 by coupling components 1228. The package-on-package structure 1234 may include a first IC package 1226 and a second IC package 1232 coupled together by coupling components 1230 such that the first IC package 1226 is disposed between the circuit board 1202 and the second IC package 1232. The coupling components 1228, 1230 may take the form of any of the examples of the coupling components 1216 discussed above, and the IC packages 1226, 1232 may take the form of any of the examples of the IC package 1220 discussed above. The package-on-package structure 1234 may be configured in accordance with any of the package-on-package structures known in the art.

FIG. 13 is a block diagram of an example electrical device 1300 that may include and/or be applied with one or more of the example dielectric films. For example, any suitable ones of the components of the electrical device 1300 may include one or more of the device assemblies 1200, IC devices 1000, or dies 902 disclosed herein. A number of components are illustrated in FIG. 13 as included in the electrical device 1300, but any one or more of these components may be omitted or duplicated, as suitable for the application. In some examples, some or all of the components included in the electrical device 1300 may be attached to one or more motherboards. In some examples, some or all of these components are fabricated onto a single system-on-a-chip (SoC) die.

Additionally, in various examples, the electrical device 1300 may not include one or more of the components illustrated in FIG. 13, but the electrical device 1300 may include interface circuitry for coupling to the one or more components. For example, the electrical device 1300 may not include a display device 1306, but may include display device interface circuitry (e.g., a connector and driver circuitry) to which a display device 1306 may be coupled. In another set of examples, the electrical device 1300 may not include an audio input device 1324 or an audio output device 1308, but may include audio input or output device interface circuitry (e.g., connectors and supporting circuitry) to which an audio input device 1324 or audio output device 1308 may be coupled.

The electrical device 1300 may include a processing device 1302 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1302 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1300 may include a memory 1304, which may itself include one or more memory devices such as volatile memory (e.g., dynamic random access memory (DRAM)), nonvolatile memory (e.g., read-only memory (ROM)), flash memory, solid state memory, and/or a hard drive. In some examples, the memory 1304 may include memory that shares a die with the processing device 1302. This memory may be used as cache memory and may include embedded dynamic random access memory (eDRAM) or spin transfer torque magnetic random access memory (STT-MRAM).

In some examples, the electrical device 1300 may include a communication chip 1312 (e.g., one or more communication chips). For example, the communication chip 1312 may be configured for managing wireless communications for the transfer of data to and from the electrical device 1300. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

The communication chip 1312 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1312 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2312 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1312 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1312 may operate in accordance with other wireless protocols in other examples. The electrical device 1300 may include an antenna 1322 to facilitate wireless communications and/or to receive other wireless communications (such as AM or FM radio transmissions).

In some examples, the communication chip 1312 may manage wired communications, such as electrical, optical, or any other suitable communication protocols (e.g., the Ethernet). As noted above, the communication chip 1312 may include multiple communication chips. For instance, a first communication chip 1312 may be dedicated to shorter-range wireless communications such as Wi-Fi or Bluetooth, and a second communication chip 1312 may be dedicated to longer-range wireless communications such as global positioning system (GPS), EDGE, GPRS, CDMA, WiMAX, LTE, EV-DO, or others. In some examples, a first communication chip 1312 may be dedicated to wireless communications, and a second communication chip 1312 may be dedicated to wired communications.

The electrical device 1300 may include battery/power circuitry 1314. The battery/power circuitry 1314 may include one or more energy storage devices (e.g., batteries or capacitors) and/or circuitry for coupling components of the electrical device 1300 to an energy source separate from the electrical device 1300 (e.g., AC line power).

The electrical device 1300 may include a display device 1306 (or corresponding interface circuitry, as discussed above). The display device 1306 may include any visual indicators, such as a heads-up display, a computer monitor, a projector, a touchscreen display, a liquid crystal display (LCD), a light-emitting diode display, or a flat panel display.

The electrical device 1300 may include an audio output device 1308 (or corresponding interface circuitry, as discussed above). The audio output device 1308 may include any device that generates an audible indicator, such as speakers, headsets, or earbuds.

The electrical device 1300 may include an audio input device 1324 (or corresponding interface circuitry, as discussed above). The audio input device 1324 may include any device that generates a signal representative of a sound, such as microphones, microphone arrays, or digital instruments (e.g., instruments having a musical instrument digital interface (MIDI) output).

The electrical device 1300 may include a GPS device 1318 (or corresponding interface circuitry, as discussed above). The GPS device 1318 may be in communication with a satellite-based system and may receive a location of the electrical device 1300, as known in the art.

The electrical device 1300 may include any other output device 1310 (or corresponding interface circuitry, as discussed above). Examples of the other output device 1310 may include an audio codec, a video codec, a printer, a wired or wireless transmitter for providing information to other devices, or an additional storage device.

The electrical device 1300 may include any other input device 1320 (or corresponding interface circuitry, as discussed above). Examples of the other input device 1320 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1300 may have any desired form factor, such as a hand-held or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device. In some examples, the electrical device 1300 may be any other electronic device that processes data.

Example methods, apparatus, systems, and articles of manufacture to improve signal integrity and reduce cross-talk in PCB assemblies are disclosed herein. Further examples and combinations thereof include the following:

Example 1 includes an apparatus comprising a substrate, the substrate having a first side and a second side opposite the first side, the first side and the second side defining a height of the substrate, traces on the first side of the substrate, and a dielectric film positioned on the first side to cover at least a portion of the traces.

Example 2 includes the apparatus as defined in example 1, wherein the substrate includes a printed circuit board (PCB), and wherein the traces include microstrip traces.

Example 3 includes the apparatus as defined in any of examples 1 or 2, wherein the first side of the substrate includes a first outer surface, and wherein the second side includes a second outer surface, wherein the second outer surface is adjacent an isolating ground layer of the substrate.

Example 4 includes the apparatus as defined in any of examples 1 to 3, wherein the substrate and the dielectric film have an impedance value in a range from approximately 75Ω to 95Ω.

Example 5 includes the apparatus as defined in any of examples 1 to 4, wherein the dielectric film includes a dielectric substrate with an adhesive.

Example 6 includes the apparatus as defined in example 5, wherein the dielectric substrate includes polyamide.

Example 7 includes the apparatus as defined in example 1, wherein the dielectric film and the substrate corresponds to a dielectric constant (Dk) value in a range from approximately 3.0 to 4.5.

Example 8 includes the apparatus as defined in example 1, wherein the height is a first height, and wherein the dielectric film includes a second height, a ratio of the second height to the first height being in a range from approximately 0.90 to 1.10.

Example 9 includes an assembly comprising a substrate including at least one substrate layer, at least one ground layer on a first side of the substrate, and traces positioned on an outer surface that at least partially defines a second side of the substrate, the second side opposite the first side, and a dielectric film positioned on the outer surface to cover at least a portion of the traces.

Example 10 includes the assembly of example 9, wherein the substrate includes a printed circuit board (PCB), and wherein the traces include microstrip traces.

Example 11 includes the assembly as defined in any of examples 9 or 10, wherein the dielectric film and the PCB correspond to an impedance value in a range from approximately 75Ω to 95Ω.

Example 12 includes the assembly as defined in examples 9 to 11, wherein the dielectric film and the substrate correspond to a dielectric constant (Dk) value in a range from approximately 3.0 to 4.5.

Example 13 includes the assembly as defined in any of examples 9 to 12, wherein the at least one substrate layer includes a first height, and wherein the dielectric film includes a second height, a ratio of the second height to the first height being in a range from approximately example 0.90 to 1.10.

Example 14 includes the assembly as defined in any of examples 9 to 13, wherein the traces are differential traces.

Example 15 includes the assembly as defined in any of examples 9 to 13, wherein the traces are single-ended traces.

Example 16 includes the assembly as defined in any of examples 9 to 15, wherein the dielectric film includes a dielectric substrate and an adhesive.

Example 17 includes a method comprising aligning a dielectric film to an outer surface of a substrate, and coupling the dielectric film to the outer surface to cover at least a portion of traces on the outer surface of the substrate.

Example 18 includes the method of example 17, wherein the substrate includes a printed circuit board (PCB), and wherein the traces include microstrip traces.

Example 19 includes the method as defined in any of examples 17 or 18, further including determining dielectric properties of the substrate, and selecting the dielectric film based on the determined dielectric properties.

Example 20 includes the method as defined in any of examples 17 to 19, wherein coupling the dielectric film to the outer surface includes applying the dielectric film to the outer surface as a conformal coating to cover the traces.

Example 21 includes the method as defined in any of examples 17 to 20, wherein aligning the dielectric film includes aligning the dielectric film to a region of the outer surface on which interconnects are etched.

From the foregoing, it will be appreciated that example systems, methods, apparatus, and articles of manufacture have been disclosed that enable highly effective reduction of cross-talk and signal degradation. Further, examples disclosed herein are highly compatible with existing technologies. Examples disclosed herein also utilize cost-effective components, and can be inexpensive to manufacture. Examples disclosed herein can also be quickly manufactured, thereby enabling relatively short production lead-times.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities and/or steps, the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities and/or steps, the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements or method actions may be implemented by, e.g., the same entity or object. Additionally, although individual features may be included in different examples or claims, these may possibly be combined, and the inclusion in different examples or claims does not imply that a combination of features is not feasible and/or advantageous.

The following claims are hereby incorporated into this Detailed Description by this reference. Although certain example systems, methods, apparatus, and articles of manufacture have been disclosed herein, the scope of coverage of this patent is not limited thereto. On the contrary, this patent covers all systems, methods, apparatus, and articles of manufacture fairly falling within the scope of the claims of this patent.

What is claimed is:

1. An apparatus comprising:
a substrate, the substrate having a first side and a second side opposite the first side, the first side and the second side defining a height of the substrate;
traces on the first side of the substrate; and
a dielectric film positioned on the first side to cover at least a portion of the traces.

2. The apparatus as defined in claim 1, wherein the substrate includes a printed circuit board (PCB), and wherein the traces include microstrip traces.

3. The apparatus as defined in claim 1, wherein the first side of the substrate includes a first outer surface, and wherein the second side includes a second outer surface, wherein the second outer surface is adjacent an isolating ground layer of the substrate.

4. The apparatus as defined in claim 1, wherein the substrate and the dielectric film have an impedance value in a range from approximately 75Ω to 95 Ω.

5. The apparatus as defined in claim 1, wherein the dielectric film includes a dielectric substrate with an adhesive.

6. The apparatus as defined in claim 5, wherein the dielectric substrate includes polyamide.

7. The apparatus as defined in claim 1, wherein the dielectric film and the substrate corresponds to a dielectric constant (Dk) value in a range from approximately 3.0 to 4.5.

8. The apparatus as defined in claim 1, wherein the height is a first height, and wherein the dielectric film includes a second height, a ratio of the second height to the first height being in a range from approximately 0.90 to 1.10.

9. An assembly comprising:
a substrate including:
at least one substrate layer,
at least one ground layer on a first side of the substrate, and
traces positioned on an outer surface that at least partially defines a second side of the substrate, the second side opposite the first side; and
a dielectric film positioned on the outer surface to cover at least a portion of the traces.

10. The assembly of claim 9, wherein the substrate includes a printed circuit board (PCB), and wherein the traces include microstrip traces.

11. The assembly as defined in claim 9, wherein the dielectric film and the substrate correspond to an impedance value in a range from approximately 75Ω to 95 Ω.

12. The assembly as defined in claim 9, wherein the dielectric film and the substrate correspond to a dielectric constant (Dk) value in a range from approximately 3.0 to 4.5.

13. The assembly as defined in claim 9, wherein the at least one substrate layer includes a first height, and wherein the dielectric film includes a second height, a ratio of the second height to the first height being in a range from approximately 0.90 to 1.10.

14. The assembly as defined in claim 9, wherein the traces are differential traces.

15. The assembly as defined in claim 9, wherein the traces are single-ended traces.

16. The assembly as defined in claim 9, wherein the dielectric film includes a dielectric substrate and an adhesive.

17. A method comprising:
aligning a dielectric film to an outer surface of a substrate; and
coupling the dielectric film to the outer surface to cover at least a portion of traces on the outer surface of the substrate.

18. The method of claim 17, wherein the substrate includes a printed circuit board (PCB), and wherein the traces include microstrip traces.

19. The method as defined in claim 17, further including:
determining dielectric properties of the substrate; and
selecting the dielectric film based on the determined dielectric properties.

20. The method as defined in claim 17, wherein coupling the dielectric film to the outer surface includes applying the dielectric film to the outer surface as a conformal coating to cover the traces.

21. The method as defined in claim 17, wherein aligning the dielectric film includes aligning the dielectric film to a region of the outer surface on which interconnects are etched.
